(19) United States
(12) Patent Application Publication
(10) Pub. No.: US 2003/0047130 A1
(43) Pub. Date: Mar. 13, 2003

(54) Process for eliminating neck dislocations during czochralski crystal growth

(75) Inventors: Hariprasad Sreedharamurthy, Ballwin, MO (US); Vijay Nithianathan, St. Charles, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/230,609

(22) Filed: Aug. 29, 2002

Related U.S. Application Data
(60) Provisional application No. 60/315,846, filed on Aug. 29, 2001.

(51) Int. Cl. C30B 15/00; C30B 21/06; C30B 27/02; C30B 30/04; C30B 28/10

(52) U.S. Cl. 117/13

(57) ABSTRACT

A process for eliminating dislocations in a neck of a large-diameter single crystal silicon ingot is provided. The process comprises controlling heat transfer at the melt/solid interface to eliminate dislocations over a reduced axial length in the neck portion of a large-diameter single crystal silicon ingot grown in accordance with the Czochralski method, thereby increasing overall process throughput and yield.

### CROSS-REFERENCE TO RELATED APPLICATIONS

This application claims priority from U.S. Provisional Application Serial No. 60/315,846, filed Aug. 29, 2001, the disclosure of which is hereby incorporated herein in its entirety.

### BACKGROUND OF THE INVENTION

The present invention generally relates to the preparation of semiconductor grade single crystal silicon, used in the manufacture of electronic components. More particularly, the present invention relates to a process for preparing a single crystal silicon ingot having a large diameter, in accordance with the Czochralski method, wherein the heat transfer at the melt/solid interface is controlled to eliminate dislocations in the neck portion over a reduced axial length.

Single crystal silicon, which is the starting material for most processes for the fabrication of semiconductor electronic components, is commonly prepared by the Czochralski (“Cz”) method. In this method, polycrystalline silicon (“polysilicon”) is charged to a crucible and melted, a seed crystal is brought into contact with the molten silicon and a single crystal is grown by slow extraction. As crystal growth is initiated, dislocations are generated in the crystal from the thermal shock of contacting the seed crystal with the melt. These dislocations are propagated throughout the growing crystal and multiplied unless they are eliminated in a neck region between the seed crystal and the main body of the crystal.

The conventional method of eliminating dislocations within a silicon single crystal (known as the Dash neck method) involves growing a neck having a small diameter (e.g., 2 to 4 mm) at a high crystal pull rate (e.g., as high as 6 mm/min.), to completely eliminate dislocations before initiating growth of the main body of crystal. Generally, dislocations can be eliminated in these small diameter necks after approximately 100 to about 125 mm of neck is grown. Once the dislocations have been eliminated, the diameter of the crystal is enlarged to form a crown or taper portion. When the desired diameter of the crystal is reached, the cylindrical main body is then grown to have an approximately constant diameter. The diameter is maintained by controlling the pull rate and the melt temperature while compensating for the decreasing melt level.

It is well known in the art that the neck, which is the weakest part of the silicon single crystal, can fracture during crystal growth, causing the body of crystal to drop into the crucible. Thus, conventional crystals having a Dash neck are typically grown to a weight of 100 kg or less to minimize stress on the neck. However, in recent years, progress in the semiconductor industry has created an ever-increasing demand for larger silicon wafers of a high quality. Particularly, more highly integrated semiconductor devices have resulted in increased chip areas and a demand for the production of silicon wafers having a diameter of 200 mm (8 inches) to 300 mm (12 inches) or more. This has resulted in the need for more effective neck growth processes which enable the elimination of dislocations and the prevention of neck fractures, while supporting the growth of single crystal silicon ingots weighing up to 300 kg or more.

A general solution for preventing neck fractures in larger crystals is to increase the neck diameter. However, large diameter necks are generally undesirable, as they require larger seed crystals, which in turn produce a higher density of slip dislocations when contacted with the silicon melt. Thus, larger diameter neck portions require increased length, typically 175 mm or more depending on the diameter of the neck, and thus additional process time, to effectively eliminate slip dislocations.

In order to minimize the generation of slip dislocations in a larger diameter Dash neck, Japanese laid-open application (Kokai) No. 4-104988 proposes a process using a seed crystal having a unique, conical shape at its apex. However, the unique seed crystal is complicated and expensive to process. Because the seed crystal is unique, a new seed crystal is needed for each crystal growth attempt, regardless of whether dislocation-free growth is achieved. Thus, changing the seed crystal requires excessive process down-time, which adversely affects productivity. Furthermore, the process employs a heater embedded in the seed crystal holder. Having such a heater makes it more difficult to form a temperature gradient between the seed crystal and the neck portion, which requires the single crystal to be pulled at an extremely slow rate.

Another process for eliminating dislocations in a larger diameter Dash neck is disclosed in Japanese laid-open application (Kokai) No. 11-199384. Specifically, the application discloses a process whereby the length of the neck required to eliminate slip dislocations is shortened by repeatedly changing the neck diameter. The neck therefore has alternating sections of increased and decreased diameter, the reference describing the increased portion as having a diameter at least twice that of the decreased portion. However, while this process is said to provide a shorter length neck for growing large diameter silicon single crystals, the process is complicated and difficult to control because of the large difference in diameter between the increased and decreased portions, and because the target diameter of the neck must be constantly changed.

In view of the forgoing, it can be seen that a need continues to exist for a process that enables large diameter ingots of substantial weight to be grown by means of a neck having a comparably large diameter but short length.

### SUMMARY OF THE INVENTION

Among the several features of the invention, therefore, may be noted the provision of a single crystal silicon ingot having a large diameter or mass, as well as a process for the production thereof; the provision of such a process wherein the throughput and yield are increased; the provision of such a process wherein the ingot has a large diameter neck; the provision of such a process wherein slip dislocations are eliminated in the neck over a substantially reduced length; and, the provision of such a process wherein a standard seed crystal is used.

Briefly, therefore, the present invention is directed to a process for eliminating dislocations in a neck of a single crystal silicon ingot, grown in accordance with the Czochralski method. The process comprises heating polycrystalline silicon in a crucible to form a silicon melt and contacting a seed crystal to the melt until the seed crystal begins to melt. As the seed crystal is contacted to the melt, dislocations are formed in the seed crystal. The seed crystal is then withdrawn from the melt to grow a neck portion of an ingot. During the withdrawal, dislocations are eliminated from the neck by controlling heat transfer at the melt/solid interface to change the shape of the melt/solid interface from concave to convex. After dislocations are removed from the neck, an an outwardly flaring seed-cone is grown adjacent the neck portion of the ingot; and a main body of the ingot is grown adjacent the outwardly flaring seed-cone.

In another embodiment, the present invention is directed to a process for eliminating dislocations in a neck of a single crystal silicon ingot, grown in accordance with the Czochralski method. The process comprises heating polycrystalline silicon in a crucible to form a silicon melt and contacting a seed crystal to the melt until the seed crystal begins to melt. As the seed crystal begins to melt, dislocations are formed in the seed crystal. The seed crystal is then withdrawn from the melt to grow a neck portion of the ingot and to eliminate dislocations such that the neck has a diameter of at least about 5 mm and a length of less than about 175 mm. The process is further characterized in that during the withdrawal, dislocations are eliminated from the neck by controlling heat transfer at the melt/solid interface. The process further comprises growing an outwardly flaring seed-cone adjacent the neck portion of the ingot; and, growing a main body adjacent the outwardly flaring seed-cone.

Other objects and features of this invention will be in part apparent and in part pointed out hereinafter.

### BRIEF DESCRIPTION OF THE DRAWINGS

FIG. 1 is a diagram generally illustrating the direction of slip dislocation growth as the shape of the melt/solid interface changes from concave to convex.

FIG. 2 is a vertical section illustrating the upper region of a single crystal generally embodying the present invention.

FIG. 3 is a schematic, fragmentary cross section of a Czochralski crystal growing apparatus showing a silicon crystal being pulled from a melt contained in the crystal growing apparatus and a reflector assembly as it is positioned during growth of a silicon crystal.

FIG. 4A is a graph of the number of dislocations as a function of neck length for necks grown in accordance with Example 1 of the present invention.

FIG. 4B is a graph showing the neck length required to eliminate dislocations as a function of reflector height, Hr, for necks grown in accordance with Example 1 of the present invention.

FIG. 5A is a graph of the number of dislocations as a function of neck length for necks grown in accordance with Example 2 of the present invention.

FIG. 5B is a graph showing the neck length required to eliminate dislocations as a function of reflector height, Hr, for necks grown in accordance with Example 2 of the present invention.

### DETAILED DESCRIPTION OF THE PREFERRED EMBODIMENTS

In accordance with the process of the present invention, it has been discovered that slip dislocations can be eliminated in the neck portion of a single crystal silicon ingot, grown in accordance with the Czochralski method, over a much shorter length or distance, even for ingots having a large diameter and substantial weight. More specifically, it has been discovered that, in comparison to conventional methods for growing large diameter and/or large mass single crystal silicon ingots, the length over which slip dislocations are eliminated in the neck of a single crystal silicon ingot, even a neck having a large diameter, can be significantly reduced by controlling the heat transfer at the melt/solid interface.

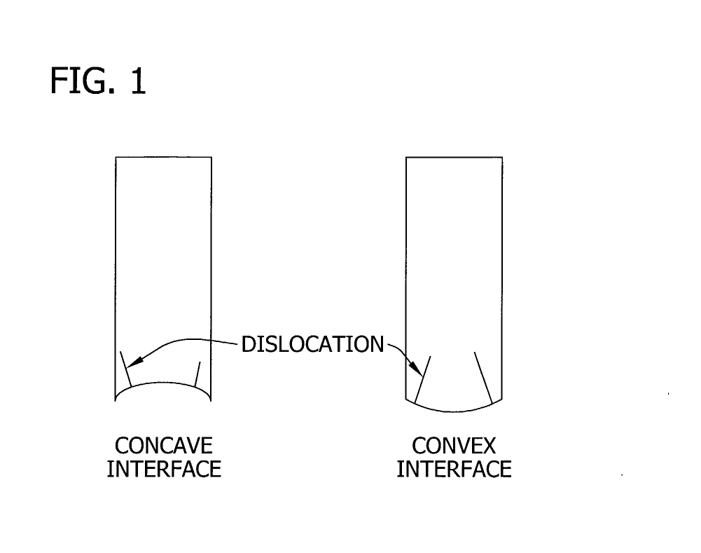

Referring now to FIG. 1, it is generally believed that, for standard growth processes wherein a normally high pull rate is employed during neck growth (e.g., greater than about 1 mm/min.), dislocations grow vertically in a generally inward direction toward the center of the neck due to the concave nature of the melt/solid interface. As a result, these dislocations continue to grow along the length of the neck until the diameter of the neck is so small that the dislocations are eliminated. For large diameter necks, such as those needed for large diameter, heavy ingots, the length of the neck which must be grown to remove these dislocations is significant (e.g., about 175 mm or more).

Without being held to a particular theory, it is generally believed that the length needed to achieve dislocation-free growth can be substantially reduced by controlling the heat transfer at the melt/solid interface to reduce the melt/solid temperature gradient, thus causing a convex melt/solid interface shape. By causing the melt/solid interface shape to be convex, the dislocations, which generally develop normal to the interface as described above, are more effectively concentrated at the circumferential edge of the neck as shown in FIG. 1, which facilitates dislocation removal. Thus, causing the interface shape to be convex results in the elimination of dislocations over a much shorter axial distance or length (e.g., less than about 175 mm) for large diameter, heavy ingots.

Accordingly, unlike existing Dash-neck processes, wherein (i) relatively small diameter ingots (e.g., ingots less than about 150 or even about 100 mm in diameter) are grown by a process wherein fast pull rates (e.g., about 6 mm/min. or more) are employed during growth of a neck having a diameter of less than about 4 mm (e.g., from about 2 to about 4 mm) and a length of less than about 100 mm, or (ii) larger diameter ingots (e.g., ingots greater than about 150 mm in diameter) are grown by various processes wherein the neck has a large diameter (e.g., greater than about 5 mm) and a length of greater than about 150 mm, the present invention enables the safe and efficient growth of heavy, large diameter single crystal silicon ingots by means of a process wherein a large diameter neck having a comparably short length is formed. More specifically, as further described herein, the process of the present invention involves controlling heat transfer at the melt/solid interface in order to form a dislocation-free neck having a diameter of greater than about 5 mm (e.g., greater than about 6, 8, 10 mm or more) and a length of less than about 175 mm (e.g., less than about 160, 140, 120, 100, 80, 60 or 40 mm), which is capable of supporting large diameter (e.g., about 200, 300 mm or more), heavy weight (e.g., about 100, 200, 300, 400 kilograms or more) single crystal silicon ingots. Preferably, the process of the present invention involves controlling heat transfer at the melt/solid interface in order to grow a large diameter, heavy weight silicon crystal with a neck having a diameter of from about 5 mm to about 10 mm (e.g. from about 6 mm to about 8 mm) and a length of from about 40 mm to about 175 mm (e.g. from about 80 mm to about 120 mm).

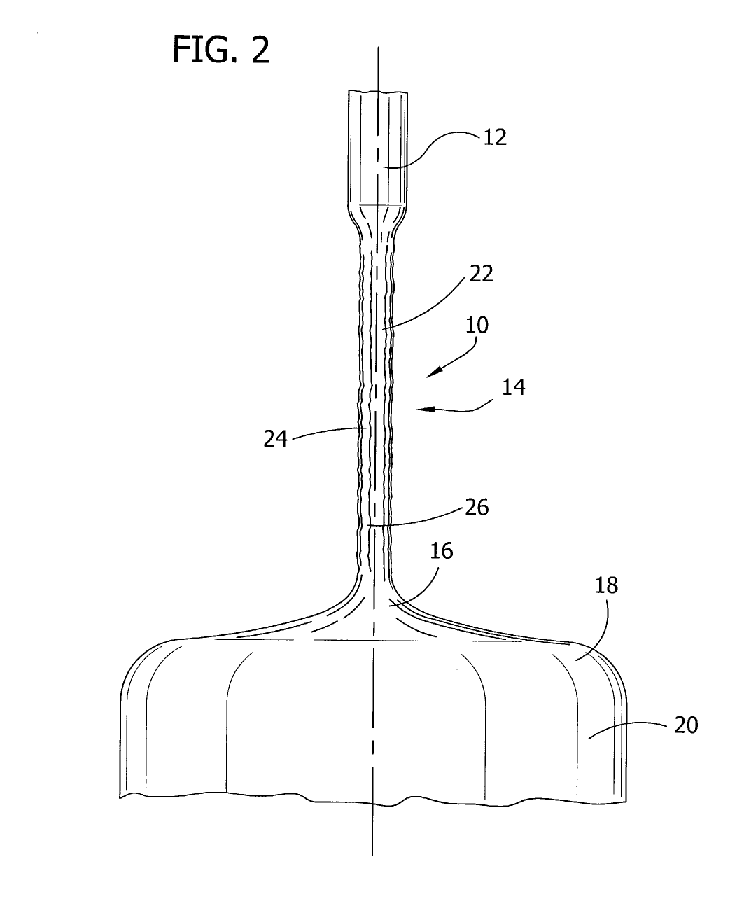

In accordance with the present process, and the Czochralski method generally, and referring now to FIG. 2, there is shown a single crystal 10 having a seed crystal 12, a neck 14, a seed cone 16, a shoulder 18 and a body 20. Once a dislocation-free seed crystal 12 is brought into contact with the surface of the molten semiconductor material, such as silicon, by controlling the heat transfer at the melt/solid interface, a neck 14 is formed which typically has: (i) an upper portion 22, grown beneath the seed crystal having dislocations (not shown); (ii) an intermediate portion 24, grown beneath the upper portion, having fewer dislocations; and, (iii) a lower portion 26, grown beneath the intermediate portion, which is free of dislocations.

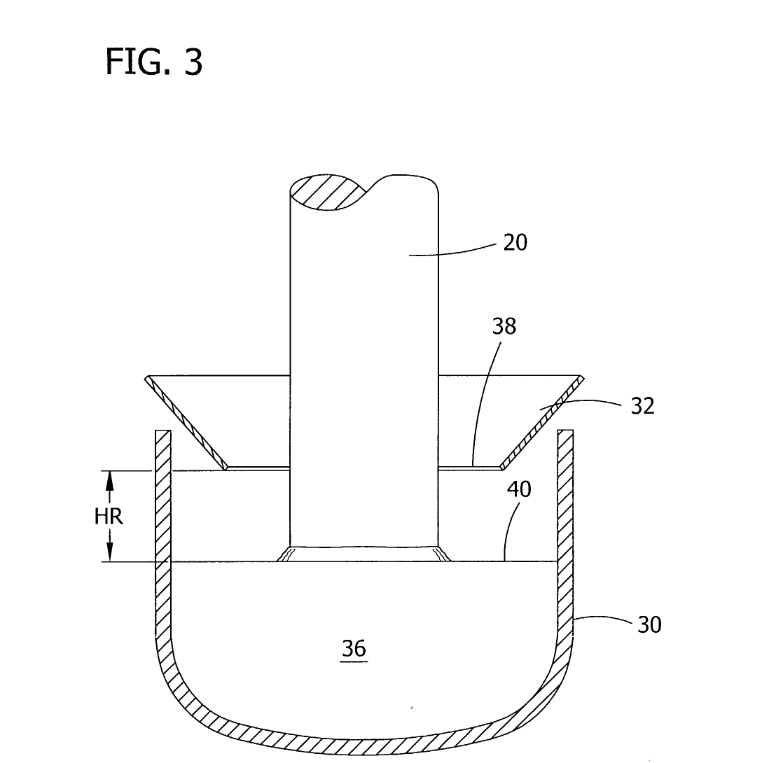

In a first embodiment of the present invention, heat transfer at the melt/solid interface is controlled by a device such as a reflector, a radiation shield, a heat shield, an insulating ring, a purge tube, a light pipe, or any other similar device capable of manipulating a temperature gradient known generally to one skilled in the art. Heat transfer may also be controlled by adjusting the power supplied to heaters below or adjacent to the crystal melt. In a preferred embodiment, heat transfer at the melt/solid interface is controlled using a reflector in proximity to the melt surface as shown in FIG. 3. Thus, the remainder of the discussion will be directed to the use of a reflector. However, it should be noted that the present invention is equally applicable to the other heat transfer control devices listed above.

Referring now to FIG. 3, a portion of a Czochralski crystal growing apparatus is shown comprising a crucible 30 and an exemplary reflector assembly 32 during growth of a silicon crystal 20. As is known in the art, hot zone apparatus, such as the reflector assembly 32, is often disposed within crucible 30 for thermal and/or gas flow management purposes. For example, reflector 32 is, in general, a heat shield adapted to retain heat underneath itself and above melt 36. Those skilled in the art are familiar with various reflector designs and materials (e.g., graphite and gray quartz). As shown in FIG. 3, reflector assembly 32 has an inner surface 38 that defines a central opening through which crystal 20 is pulled from the crystal melt 36.

Generally, it has been found that the temperature gradient above the melt surface 40, and thus heat transfer at the melt/solid interface, can be controlled by varying the reflector height above the melt surface, as further described hereinbelow. Typically, this reflector height (or melt gap), referred to herein as Hr, is measured as the distance between the bottom edge of the reflector 32 and the melt surface 40. The reflector height, Hr, can be varied by either adjusting the position of the reflector apparatus 32 in the hot zone (relative to the surface of the melt 40, for example) or by adjusting the position of the melt surface 40 in the hot zone (relative to the reflector 32, for example). In a preferred embodiment, the reflector 32 is in a fixed position and the reflector height, Hr, is changed by manipulating the position of the melt surface 40 by moving the crucible 30 within the crystal growing apparatus.

The reflector height can be monitored and adjusted by means known in the art, including for example the use of: (i) a vision system and a method for measuring the melt level/position inside the crystal pulling apparatus during ingot growth relative to the reflector positioned above the melt, as described in, for example, Fuerhoff et al., U.S. Pat. No. 6,171,391 (which is incorporated herein by reference); (ii) a lift or drive mechanism for raising/lowering the reflector as described in, for example, U.S. Pat. No. 5,853,480 (which is incorporated herein by reference); and/or (iii) a lift or drive mechanism for raising/lowering the crucible which contains the melt, in those instances wherein, for example, the reflector is in a fixed position above the melt surface.

The reflector height, Hr, affects the temperature gradient at the melt/solid interface by controlling the temperature above the melt. As used herein, the temperature gradient at the melt/solid interface refers to the difference in temperature of the crystal at its outer edge relative to its center. Without being held to a particular theory, it is believed that controlling the temperature gradient at the melt/solid interface affects the interface shape because the temperature of the outer edge of the crystal relative to the center of the crystal determines the shape of the melt/solid interface. If the outer edge of the crystal is much cooler than the center of the crystal, which is the case when Hr is small, the melt/solid interface shape is generally concave. Conversely, if the outer edge of the crystal is hotter than, or of similar temperature to, the center of the crystal, the melt/solid interface shape is generally convex. Thus, the reflector height can affect the melt/solid interface shape because it can control the temperature of the outer edge of the crystal. For example, when Hr is large, the reflector provides less shielding of the crystal from the heater surrounding the crucible and the sides of the crystal are hotter, which provides a smaller temperature gradient and a generally convex shape of the interface. On the other hand, when Hr is small, the crystal is shielded from the heater which provides for a cooler outer edge, a larger temperature gradient and thus, a concave interface shape.

It is important to note that the method of the present invention can be used with any conventional hot zone arrangement known in the art of Cz crystal growth wherein a reflector or other device for controlling heat transfer at the melt/solid interface is positioned above the melt; however, the value for the reflector height, Hr, will differ depending on the type of hot zone used. For example, the temperature gradient above a particular crystal melt, and thus, an appropriate reflector height, Hr, for practicing the present invention can vary depending on many factors. In particular, one skilled in the art should recognize that process conditions regarding the type of hot zone, the pull rate, seed crystal diameter, and neck diameter are important to consider. In any case, it is important to note that typically, in determining the appropriate value of Hr for specific hot zones or process conditions, generally, as the reflector height, Hr, increases, the temperature gradient at the melt/solid interface decreases.

Preferably, Hr is adjusted to decrease the temperature gradient at the melt/solid interface such that a convex melt/solid interface is established at or near the beginning of the necking step of the crystal growth process. Generally, experience to date has shown that an Hr value of from about 20 mm to about 60 mm is sufficient to provide for a convex melt/solid interface at the beginning of the necking step. More preferably, the Hr value ranges from about 30 mm to about 50 mm. Even more preferably, the Hr value ranges from about 40 mm to about 50 mm.

Although not limited to advanced hot zones, the present invention has a preferred use in advanced hot zones used with fast pull rates. An advanced hot zone contains more insulation-and/or heat shields within the crystal growth chamber, which generally result in greater temperature gradients at the melt/solid interface. A greater temperature gradient results in more slip dislocations upon contact of the seed crystal with the melt surface and the dislocations formed are more difficult to eliminate due to the increased number. Typically, when using standard fast pull process conditions in an advanced hot zone where a large temperature gradient is produced, it has been found that the process of the present invention results in the growth of large diameter, single crystal silicon ingots having neck lengths about 50% to about 75% shorter than necks grown in a conventional crystal growth process (e.g. conventional neck lengths of 175 mm or more).

In one embodiment, the process of the present invention is utilized in advanced hot zones for the production of P-type silicon. As used herein, the term “P-type” refers to silicon containing an element from Group 3 of the Periodic Table such as boron, aluminum, gallium and indium, most typically boron. P-type silicon typically has a resistivity from about 100 Ω·cm (ohm centimeters) to about 0.005 Ω·cm. For silicon doped with boron, the foregoing resistivity values correspond to a dopant concentration of about 3×10¹⁷ atoms/cm³ to about 3×10¹⁹ atoms/cm³, respectively. P-type silicon is typically further characterized based on resistivity, for example, P-type silicon having a resistivity of about 20 Ω·cm (about 4×10¹⁸ boron atoms/cm³) to about 1 Ω·cm is generally referred to as P⁻-silicon. P-type silicon having a resistivity of about 0.03 Ω·cm to about 0.01 Ω·cm is generally referred to as P⁺-silicon. A wafer having a resistivity of about 0.01 Ω·cm (about 1×10¹⁹ boron atoms/cm³) to about 0.005 Ω·cm (about 3×10¹⁹ boron atoms/cm³) is generally referred to as P⁺⁺-silicon. For purposes of the present invention, P⁺ and P⁺⁺-silicon are considered “highly P-doped silicon.”

When growing P⁻-silicon in an advanced hot zone, it has been found that the process of the present invention results in the growth of large diameter single crystal silicon ingots requiring a substantially shorter neck to eliminate dislocations. For example, by controlling heat transfer at the melt/solid interface in accordance with the the process of the present invention, it has been found that dislocations can be eliminated in a neck of a silicon single crystal which is about 50% to about 75% shorter than conventional crystal growth processes for P⁻-silicon, which typically require neck lengths ranging from 300 to 325 mm. Thus, when employed in the growth of P⁻-silicon in an advanced hot zone, the process of the present invention can produce large-diameter single crystal silicon ingots having a neck length ranging from about 175 mm to about 245 mm. More preferably, the invention results in a neck length of about 175 mm. Thus, the decreased neck length makes the necking step shorter and provides more space in the Czochralski puller to grow a silicon ingot. Therefore, larger, longer ingots can be grown in a shorter time, which increases overall crystal throughput and yield.

In another embodiment, the process of the present invention may be used to grow P⁺-silicon in an advanced hot zone as described, for example, by Chandrasekhar et al., in U.S. Pat. No. 5,628,823, which is hereby incorporated by reference. For example, it has been found that varying the value of Hr in accordance with the present invention results in a marked decrease in the length of the neck of a large diameter silicon crystal necessary to eliminate dislocations. In particular, it has been found that large-diameter silicon crystals can be grown with neck lengths which are 50% to about 75% shorter than conventional crystal growth processes operating under P⁺ process conditions, which typically necessitate a neck length of about 150 mm to eliminate dislocations within the neck. Thus, when employed in the growth of P⁺-silicon in an advanced hot zone, the process of the present invention can produce large-diameter single crystal silicon ingots having a neck length ranging from about 40 mm or less to about 100 mm to eliminate dislocations. Preferably, the invention requires a neck length of about 40 mm or less to about 70 mm to eliminate dislocations. More preferably, the invention requires a neck length of about 40 mm to about 50 mm to eliminate dislocations, even more preferably less than about 40 mm.

In a further preferred embodiment, the process of the present invention may be carried out in a “slow cool” hot zone configuration; that is, the present process may be performed in any commercial crystal puller having an open or closed hot zone which is capable of achieving the ingot residence times or cooling rates described, for example, in U.S. Pat. Nos. 6,197,111 and 5,853,480, which are incorporated herein by reference. For example, preliminary work to date shows that when employed in a “slow cool” hot zone configuration, increasing Hr from 70 mm to 100 mm reduced the neck length required to eliminate dislocations by 50%. Additionally, the crystal pulling apparatus may be fitted with an upper heater to aid with, for example, control of the cooling rate, such as that shown in PCT Application No. PCT/US00/25694, which is incorporated herein by reference.

General Process Conditions

It is to be noted that the process according to the present invention can be applied to essentially any standard Cz growth method, as well as a magnetic field-applied Cz (MCz) method, wherein for example a lateral magnetic field or a magnetic cusp field is applied during crystal growth. In addition, the crystal orientation of the seed crystal is not narrowly critical (e.g., a crystal orientation of <100> or <111> may be used, for example).

Further, it should be understood that the number of neck dislocations can be quantified and observed by any means known in the art. Such a procedure, which was employed in the Examples described below, comprises etching the neck portion of the ingot to expose the dislocations, which are observed and counted under an optical microscope. A typical etch procedure comprises contacting the neck portion with a mixed acid etch (MAE) for about 10 minutes followed by a Wright etch solution for another 10 minutes to expose the dislocations. The number of dislocations, which manifest as etch pits, are then counted for each 5 mm of neck length.

### EXAMPLES

The following Examples illustrate one approach that may be used to carry out the process of the present invention. Accordingly, these should not be interpreted in a limiting sense.

### Example 1

This example demonstrates the growth of 200 mm diameter crystals wherein various values of Hr were used during the necking portion of the Cz crystal growth process. The experiment was conducted using standard 12-mm seeds in a closed hot zone under fast pull conditions using a 140 kg charge of P⁻-silicon. The hot zone utilized a reflector to control heat transfer at the melt/solid interface.

The experiment comprised growing three crystals at Hr values of 30 mm, 40 mm and 50 mm under identical process conditions. Results of the crystal growth runs are summarized in Table 1 below.

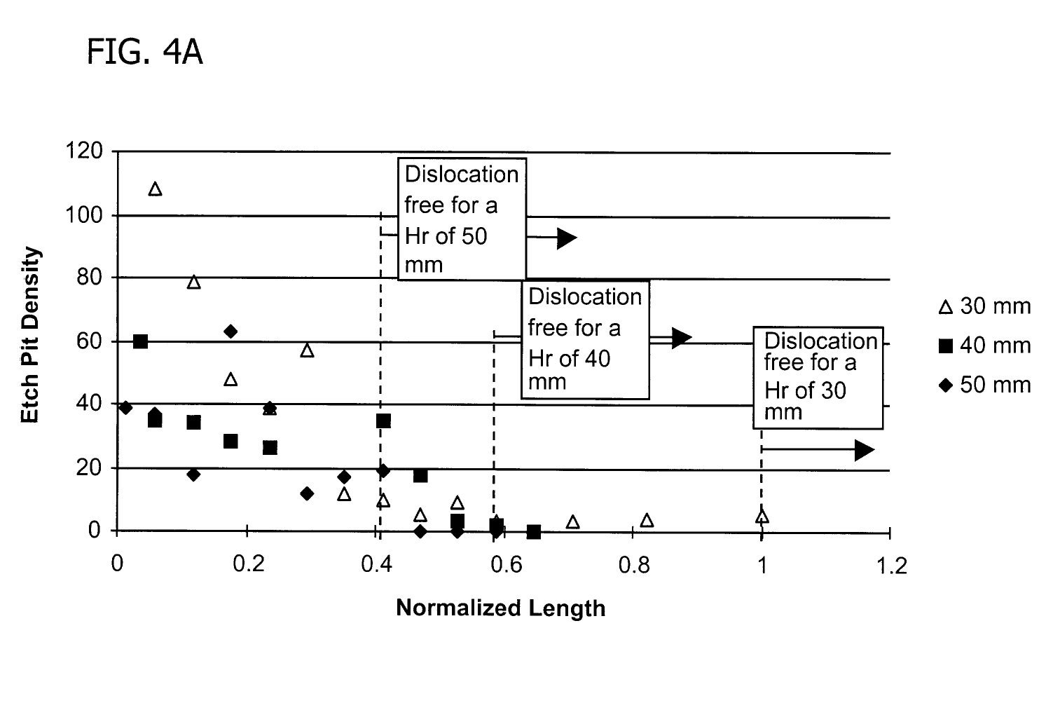

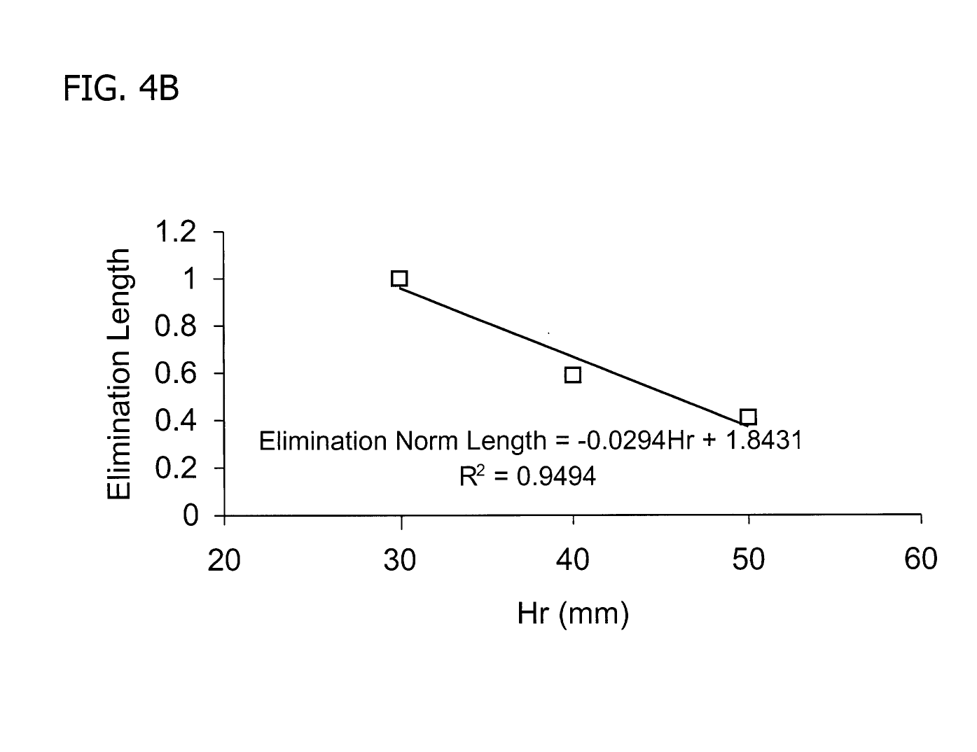

After crystal growth, the number of dislocations were determined. FIG. 4A is a graph showing the number of dislocations as a function of neck length in mm for each of the three crystals grown with an Hr of 30 mm, 40 mm, and 50 mm respectively. As shown in the graph, as the reflector height, Hr, increased, the neck length needed to completely eliminate dislocations decreased. In particular, for an Hr of 30 mm, dislocation free neck growth was not achieved (i.e., dislocations were not completely eliminated in the neck). Whereas, for an Hr of 40 mm, dislocations were eliminated in the neck (i.e., were unable to be detected after etching) at a length of 250 mm. Finally, for an Hr value of 50 mm, the dislocations were eliminated in the neck at a length of 175 mm. Thus, as shown in FIG. 4B, increasing the Hr value greatly decreased the axial neck length needed to completely eliminate dislocations.

TABLE 1

| | Normalized Length to |
|---|---|
| Hr (mm) | Eliminate Neck Dislocations |
| 30 | 1.0 |
| 40 | 0.6 |
| 50 | 0.42 |

### Example 2

This example demonstrates the growth of 200 mm diameter crystals wherein various values of Hr were used during the necking portion of the Cz crystal growth process. The experiment was identical to that described in Example 1 above except that it comprised growing three crystals at Hr values of 30 mm, 40 mm and 50 mm in an advanced hot zone using P⁺-silicon. Results of the crystal growth runs are summarized in Table 2 below.

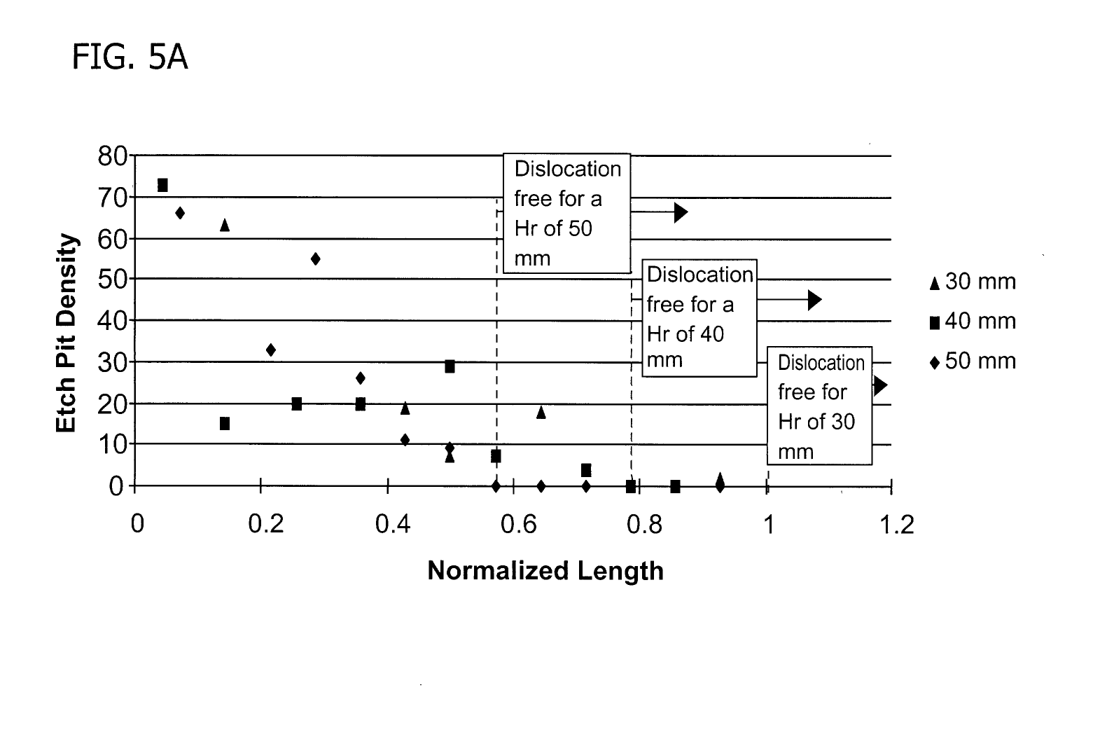

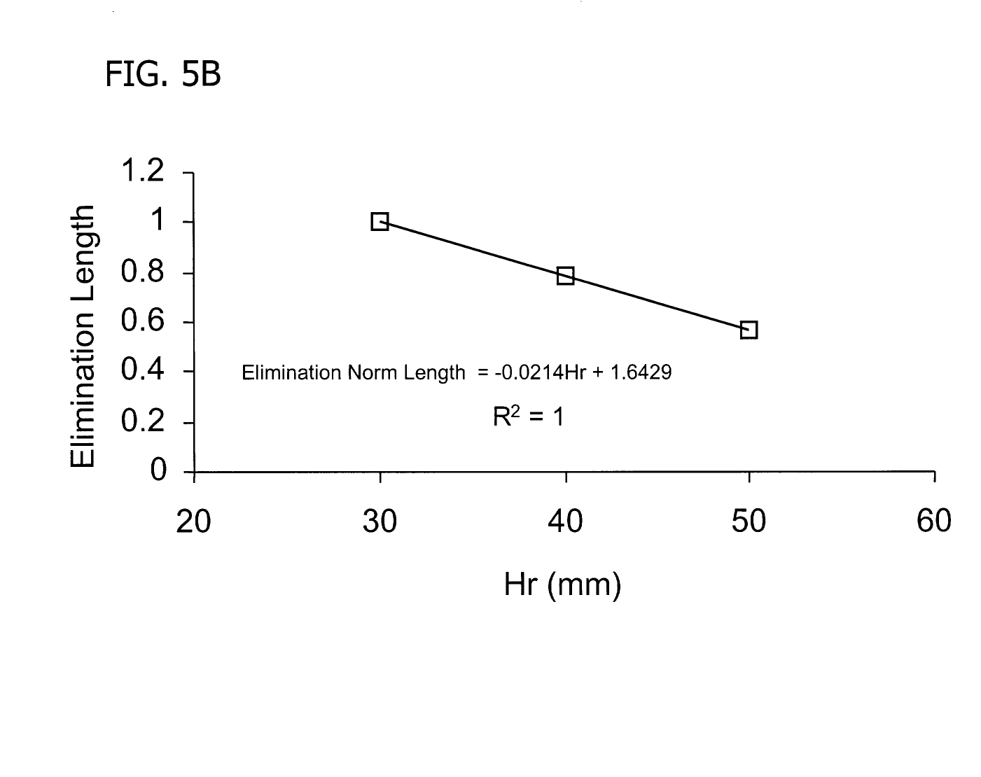

FIG. 5A is a graph showing the number of dislocations as a function of neck length in mm for each of the three crystals grown with an Hr of 30 mm, 40 mm, and 50 mm respectively. As shown in the graph, as the reflector height, Hr, was increased, the neck length needed to completely eliminate dislocations decreased. For example, crystal growth using an Hr of 30 mm required a neck length of 70 mm to eliminate dislocations in the neck. For crystal growth using an Hr of 40 mm, a neck length of 60 mm was required to eliminate dislocations. Finally, for an Hr value of 50 mm, dislocations were eliminated in a neck having a length of 40 mm. Thus, as shown in FIG. 5B, increasing the Hr value greatly decreased the axial neck length needed to completely eliminate dislocations (21% and 44% reduction respectively).

TABLE 2

| | Normalized Length to |
|---|---|
| Hr (mm) | Eliminate Neck Dislocations |
| 30 | 1.0 |
| 40 | 0.79 |
| 50 | 0.56 |

As various changes could be made in the above process without departing from the scope of the present invention, it is intended that all matter contained in the above description be interpreted as illustrative and not in a limiting sense.

What is claimed is:

1. A process for eliminating dislocations in a neck of a single crystal silicon ingot, grown in accordance with the Czochralski method, the process comprising:
heating polycrystalline silicon in a crucible to form a silicon melt;
contacting a seed crystal to the melt until the seed crystal begins to melt, forming dislocations therein;
withdrawing the seed crystal from the melt to grow a neck portion of the ingot, wherein during the withdrawal dislocations are eliminated from the neck by controlling heat transfer at the melt/solid interface to change the shape of the melt/solid interface from concave to convex;
growing an outwardly flaring seed-cone adjacent the neck portion of the ingot; and,
growing a main body adjacent the outwardly flaring seed-cone.

2. A process as set forth in claim 1 wherein heat transfer at the melt/solid interface is controlled by adjusting a distance, Hr, between the melt surface and a device positioned above the melt surface.

3. A process as set forth in claim 2 wherein the device is selected from the group consisting of a reflector, a radiation shield, a heat shield, an insulating ring, a purge tube or a light pipe.

4. A process as set forth in claim 2 wherein heat transfer at the melt/solid interface is controlled by changing the position of the melt surface relative to the position of the device.

5. A process as set forth in claim 2 wherein heat transfer at the melt/solid interface is controlled by changing the position of the device relative to the position of the melt surface.

6. A process as set forth in claim 1 wherein the body has a nominal diameter of at least about 200 mm.

7. A process as set forth in claim 1 wherein the body has a nominal diameter of at least about 300 mm.

8. A process as set forth in claim 1 wherein the body has a weight of at least about 100 kilograms.

9. A process as set forth in claim 1 wherein the body has a weight of at least about 200 kilograms.

10. A process as set forth in claim 1 wherein dislocations are eliminated in the neck within an axial length of less than about 175 mm.

11. A process as set forth in claim 1 wherein dislocations are eliminated in the neck within an axial length of less than about 100 mm.

12. A process as set forth in claim 1 wherein dislocations are eliminated in the neck within an axial length of less than about 80 mm.

13. A process as set forth in claim 1 wherein dislocations are eliminated in the neck within an axial length of less than about 40 mm.

14. A process as set forth in claim 1 wherein the neck has a nominal diameter of at least about 5 mm.

15. A process as set forth in claim 1 wherein the neck has a nominal diameter of from about 6 mm to about 8 mm.

16. A process as set forth in claim 1 wherein the neck has a nominal diameter of at least about 10 mm.

17. A process for eliminating dislocations in a neck of a single crystal silicon ingot, grown in accordance with the Czochralski method, the process comprising:
heating polycrystalline silicon in a crucible to form a silicon melt;
contacting a seed crystal to the melt until the seed crystal begins to melt, forming dislocations therein;
withdrawing the seed crystal from the melt to grow a neck portion of the ingot, the neck having a diameter of at least about 5 mm and a length of less than about 175 mm, wherein during the withdrawal dislocations are eliminated from the neck by controlling heat transfer at the melt/solid interface;
growing an outwardly flaring seed-cone adjacent the neck portion of the ingot; and,
growing a main body adjacent the outwardly flaring seed-cone.

18. A process as set forth in claim 17 wherein the body has a nominal diameter of at least about 200 mm.

19. A process as set forth in claim 17 wherein the body has a nominal diameter of at least about 300 mm.

20. A process as set forth in claim 17 wherein the body has a weight of at least about 100 kilograms.

21. A process as set forth in claim 17 wherein the body has a weight of at least about 200 kilograms.

22. A process as set forth in claim 17 wherein dislocations are eliminated in the neck within an axial length of less than about 100 mm.

23. A process as set forth in claim 17 wherein dislocations are eliminated in the neck within an axial length of less than about 80 mm.

24. A process as set forth in claim 17 wherein dislocations are eliminated in the neck within an axial length of less than about 40 mm.

25. A process as set forth in claim 17 wherein the neck has a nominal diameter of from about 6 mm to about 8 mm.

26. A process as set forth in claim 17 wherein the neck has a nominal diameter of at least about 10 mm.
